(19) United States
(12) Patent Application Publication
(10) Pub. No.: US 2011/0304963 A1
(43) Pub. Date: Dec. 15, 2011

(54) ELECTRONIC DEVICE HOLDER, ESPECIALLY FOR A MOBILE PHONE, FOR USE IN A MECHANICAL VEHICLE

(75) Inventor: Slawek LUKSIK, Kosina (PL)

(73) Assignee: BURY SP Z O.O., Mielec (PL)

(21) Appl. No.: 13/113,954

(22) Filed: May 23, 2011

(30) Foreign Application Priority Data
Jun. 9, 2010 (EP) 10460022

(51) Int. Cl. H05K 5/00

(52) U.S. Cl. 361/679.01

(57) ABSTRACT

The holder for an electronic device, especially for a mobile phone, for use in a mechanical vehicle, which can also accommodate various replaceable electronic modules, especially a GPS module, or a GPS supporting module, including at least a holding unit 1, which accommodates an electronic device, and an additional replaceable element 2, which is favorably detachably connected with the said holding unit and which includes an additional replaceable electronic module 4 and an electric connector 6, which is adapted to provide an electric connection with the device.

### CROSS-REFERENCE TO RELATED APPLICATIONS

Pursuant to 35 U.S.C. § 119 and the Paris Convention Treaty, this application claims the benefit of European Patent Application No. EP10460022 filed Jun. 9, 2010, the contents of which are incorporated herein by reference in their entirety.

### BACKGROUND OF THE INVENTION

1. Field of the Invention

This invention relates to a holder for an electronic device, especially a mobile phone, to be installed in mechanical vehicles, that enables using an additional module, especially a Global Positioning Satellite (GPS) module or a GPS supporting module.

2. Description of the Related Art

In the recent years, electronic devices, especially mobile phones, which are provided with various electronic modules enabling additional functionalities, such as GPS navigation, audio and movie players, have been more often used.

Additional modules of this type are known and built-in into electronic devices, especially mobile phones, or have a form of independent modules in a separate casing, which are linked with the device by means of a cable or wirelessly.

German Utility Model DE 203 20 388 U1 discloses a mounting system for a radio-communication terminal, e.g., a hands-free set. The system is provided with a base, which is fixed immovably to the dashboard or to a central console or to a support within a vehicle, a holder, and mechanical connecting members that temporarily link the base and the holder. The holder has a first electric connector, which is adapted to engage with a second electric connector located in the base. There is a GPS receiver in the base, into which a GPS signal is fed and, then, transformed into data on the geographical position. The mounting system is provided with electric connectors, which are used to transmit the position-related data from the GPS receiver sitting in the holder to a radio-communication terminal.

German Pat. DE 103 19 114 A1 discloses a parking control system comprising a data carrier within a vehicle, which is adapted to contain saved control data on the locations of the data carrier's stay, and a portable control device for automatic reception of data concerning the controlled locations of the data carrier's stay, the portable device being connected to a global positioning system (GPS) that enables identification of a current position of the control device, to which a computing device, adapted to compare the current position of the control device to the data collected from the data carrier, is assigned.

One major inconvenience of these solutions known in the state of the art is the necessity to interconnect two separate devices with separate casings being connected by means of a cable or wirelessly.

### SUMMARY OF THE INVENTION

Therefore, it is an objective of this invention to provide a holder for an electronic device, especially a mobile phone, for a mechanical vehicle that is provided with holding elements, which are adapted to hold additional electronic modules, e.g., a GPS module or a GPS supporting module, and are connected with the holder by means of a snap-in connection.

According to the invention, there is provided a holder, comprising: a holding unit, which is adapted to accommodate an electronic device; an additional replaceable element, which, in certain embodiments, is detachably connected to the holding unit and which is adapted to hold an additional replaceable electronic module; and a connecting unit, which is adapted to provide an electric connector with the electronic device.

In certain embodiments of the invention, the additional replaceable element is provided with a slot, which has a negative shape of the additional replaceable electronic module and which is adapted to hold the additional replaceable electronic module.

In certain embodiments of the invention, the holding unit is provided with a cavity, which is located in that portion of the holding unit where the connection with the additional replaceable element is made, and into which the additional replaceable element of a shape conforming to the cavity enters.

In certain embodiments of the invention, the additional replaceable element is connected with the holding unit by means of a snap-in connection.

In certain embodiments of the invention, the snap-in connection is formed by angular oblong gaps in the holding unit and by flexible slides, which are adapted to interlock with the angular oblong gaps and are located in the additional replaceable unit. The locations of the angular oblong gaps and of the flexible slides may be interchanged.

In certain embodiments of the invention, the additional replaceable element consists of a base and a cover, between which the additional replaceable electronic module sits.

Testing of the mobile phone holder, according to the invention, proved it was a fully useful and a general-purpose holder suitable for various electronic modules connected with the primary electronic device resting in the holder.

### BRIEF DESCRIPTION OF THE DRAWINGS

The holder for an electronic device, especially for a mobile phone, for use in a mechanical vehicle, is depicted, by way of example only, in the drawings, in which:

FIG. 1 is a perspective front view of the holder, according to the invention, with the additional replaceable element, which includes the additional electronic module;

FIG. 2 is another perspective front view of the same holder with the additional replaceable element in the pushed-in position;

FIG. 3 is a perspective rear view of the holder, connected to the additional replaceable element, which includes the additional electronic module;

FIG. 4 is a perspective rear view of the same holder with the additional replaceable element in the pushed-in position;

FIG. 5 is an exploded view of the holder according to the invention; and

FIG. 6 is a perspective side view of the holder according to the invention.

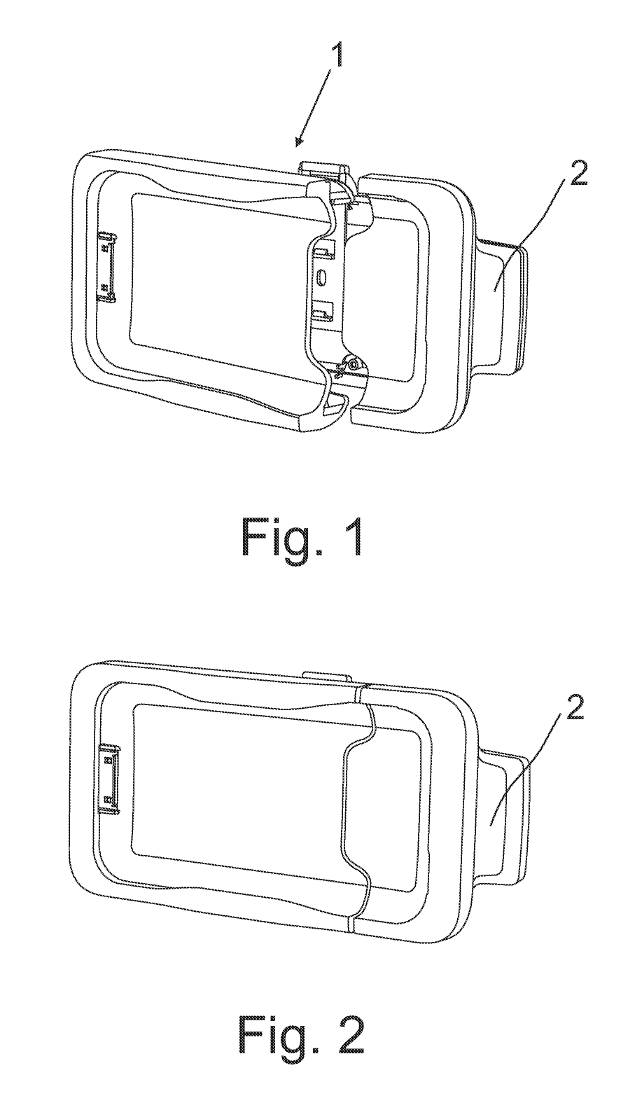

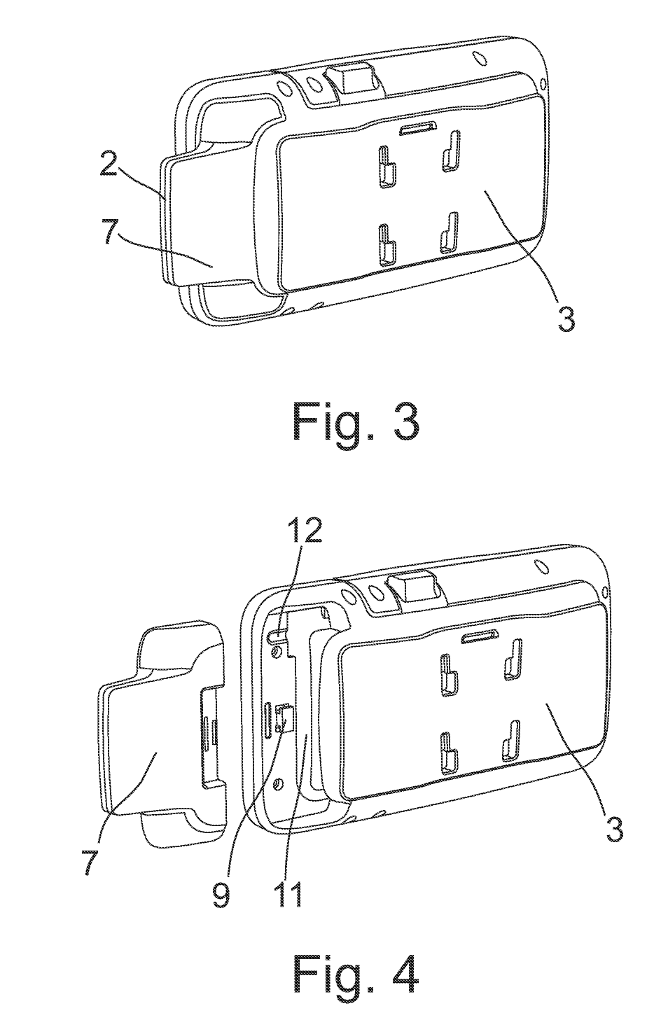

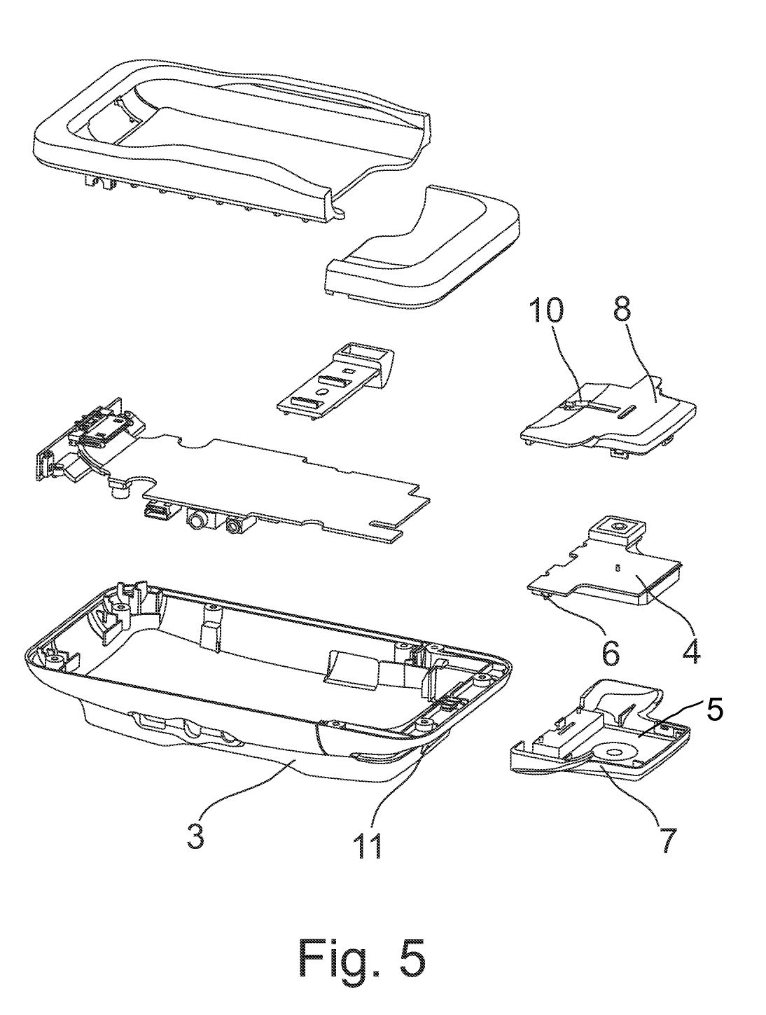

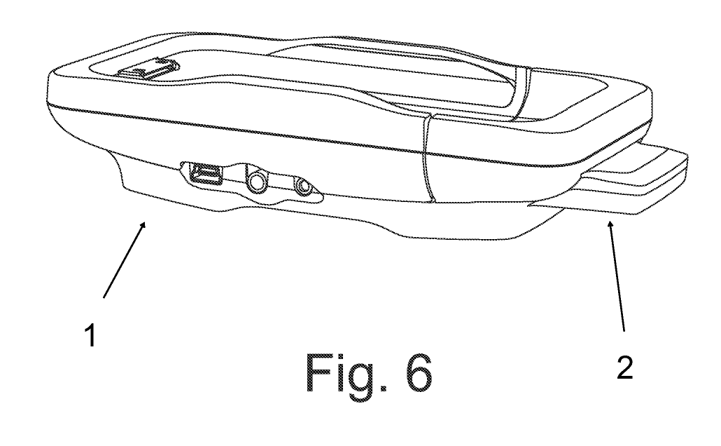

### DETAILED DESCRIPTION OF THE EMBODIMENTS

Detailed description will be given below with reference to accompanying drawings.

The holder for an electronic device, especially for a mobile phone, for use in a mechanical vehicle, comprises a holding unit 1 for an electronic device and an additional replaceable element 2, which forms a casing for an additional replaceable electronic module 4, e.g., a GPS module or a GPS supporting module.

The holding unit 1 conforms to the shape and size of the electronic device resting in it, e.g., a mobile phone, and is provided with known mounting elements that are adapted to mount the electronic device and with known electric connectors. Additionally, it is typically provided with the mounting element 3 that mounts it in the cradle fixed within the vehicle. The holding unit 1 is provided with a cavity 11, which is located in that portion of the holding unit where the connection with the additional replaceable element 2 is made, and into which the additional replaceable element 2 having a shape conforming to the cavity 11 enters.

The additional replaceable electronic module 4 is provided with a suitable electric connector 6, which is adapted to connect this module with the electronic circuits of the holding unit 1.

In one of the embodiments depicted in the drawing, the additional replaceable element 2 of the holder comprises a bi-partite casing, which consists of a base 7 and a cover 8. In the space between the base 7 and the cover 8, there is a slot 5, which has a negative shape with respect to the additional replaceable electronic module 4 mounted in the slot, e.g., a printed-circuit board with electronic elements. Other designs of the additional replaceable element 2 are possible. For example, it can have the form of a single casing provided with a slot, into which a replaceable electronic module may be inserted.

The additional replaceable element 2 of the holder is connected with the holding unit 1, favorably, by means of a snap-in connection.

In one embodiment, the snap-in connection comprises a slide 9 in the holding unit 1 and an angular oblong gap 10, adapted to interlock with the slide 9 and located in the additional replaceable element 2. However, the locations of the angular oblong gap 10 and of the slide 9 may be interchanged.

Other known joint forms may be used to connect the holder with the additional replaceable element.

The electronic device resting in the holding unit 1 is operable also when the additional replaceable element 2 with the additional replaceable electronic module 4 is disconnected from the holding unit 1.

The holder, according to the invention, is of general-purpose nature and may be used to hold various electronic devices, e.g., a Bluetooth module, a Wi-Fi module, a GPS module, an antenna interface, or other receiving and/or sending devices, whereas the additional replaceable element may be used to accommodate various additional electronic modules, e.g., hands-free sets, Bluetooth devices, Wi-Fi devices, an antenna interface.

The invention is not limited to the embodiments presented above but includes also any modifications and changes thereof, especially those aiming at making these embodiments adapted to particular electronic devices resting in the holder and to respective replaceable modules used. While this invention has been described in connection with particular examples thereof, the true scope of the invention is not so limited since other modifications will become apparent to the skilled practitioner upon a study of the drawings, specification, and following claims.

All publications and patent applications mentioned in this specification are indicative of the level of skill of those skilled in the art to which this invention pertains. All publications and patent applications mentioned in this specification are herein incorporated by reference to the same extent as if each individual publication or patent application mentioned in this specification was specifically and individually indicated to be incorporated by reference.

The invention claimed is:

1. A holder for an electronic device, comprising:
a holding unit (1); and
a replaceable element (2), comprising a replaceable electronic module (4) and an electric connector (6); wherein
said holding unit (1) is adapted to receive the electronic device;
said replaceable element (2) is connected detachably to said holding unit (1); and
said electric connector (6) is adapted to provide an electric connection with the electronic device.

2. The holder of claim 1, wherein said replaceable element (2) is provided with a slot (5), said slot (5) has a shape that is complementary to said replaceable electronic module (5); and said slot (5) is adapted to receive and hold said replaceable electronic module (4).

3. The holder of claim 1, wherein said holding unit (1) is provided with a cavity (11); said cavity (11) is located in a portion of said holding unit (1) in which a connection with said replaceable element (2) is made; said replaceable element (2) has a shape conforming to said cavity (11); and said replaceable element (2) enters into said cavity (11).

4. The holder of claim 1, wherein said replaceable element (2) is connected with said holding unit (1) by a snap-in connection.

5. The holder of claim 4, wherein said snap-in connection is formed between flexible slides (9) disposed in said holding unit (1) and angular oblong gaps (10) disposed in said replaceable element (2), said angular oblong gaps (10) being adapted to interlock with the said slides (9).

6. The holder of claim 4, wherein said snap-in connection is formed between flexible slides (9) disposed in said replaceable element (2) and angular oblong gaps (10) disposed in said holding unit (1), said angular oblong gaps (10) being adapted to interlock with the said slides (9).

7. The holder of claim 1, wherein said replaceable element (2) comprises a base (7) and a cover (8); and said replaceable electronic module (4) is disposed between said base (7) and said cover (8).

8. The holder of claim 1 disposed in a mechanical vehicle.

9. The holder of claim 1, wherein the electronic device is a mobile phone.

10. The holder of claim 1, wherein the holder accommodates one or more various replaceable electronic modules.

11. The holder of claim 1, wherein said replaceable electronic module (4) is a GPS module or a GPS supporting module.
